(19) United States
(12) Patent Application Publication
(10) Pub. No.: US 2025/0182795 A1
(43) Pub. Date: Jun. 5, 2025

(54) SEMICONDUCTOR DEVICE AND METHOD FOR FABRICATING THE SAME

(71) Applicant: SK hynix Inc., Gyeonggi-do (KR)

(72) Inventors: Hong Seong KANG, Gyeonggi-do (KR); Byung Ho LEE, Gyeonggi-do (KR); Ilsup JIN, Gyeonggi-do (KR); Jin Won PARK, Gyeonggi-do (KR); Kang Sik CHOI, Gyeonggi-do (KR)

(21) Appl. No.: 18/963,757

(22) Filed: Nov. 29, 2024

(30) Foreign Application Priority Data
Nov. 30, 2023 (KR) 10-2023-0171285
Nov. 27, 2024 (KR) 10-2024- 0171665

(51) Int. Cl. G11C 5/06; H10B 12/00

(52) U.S. Cl. CPC G11C 5/06; H10B 12/03; H10B 12/09; H10B 12/315; H10B 12/482; H10B 12/488; H10B 12/50

(57) ABSTRACT

A semiconductor device includes a first substrate; a memory cell array, a second substrate, and a back-side power distribution network. The memory cell array includes memory cells that are vertically stacked over the first substrate. The second substrate including a front side facing the memory cell array and a back side at a higher level than the front side. The second substrate further includes a plurality of control circuits for controlling the memory cells. The back-side power distribution network includes a power interconnection that penetrates the second substrate and supplies power to the control circuits from the back side of the second substrate. The memory cell array is electrically connected to the plurality of control circuits of the second substrate by a bonding structure.

### CROSS-REFERENCE TO RELATED APPLICATIONS

The present application claims priority under 35 U.S.C 119(a) to Korean Patent Application No. 10-2023-0171285 and No. 10-2024-0171665, respectively filed on Nov. 30, 2023, and Nov. 27, 2024, which is incorporated herein by reference in its entirety.

### BACKGROUND

### 1. Field

Exemplary embodiments of the present disclosure relate to a semiconductor device and a method for fabricating the same.

### 2. Description of the Related Art

Semiconductor memory devices continue to be in high demand. In order to provide for large capacity and fine-patterning of memory devices, three-dimensional (3D) memory devices have been developed to include a stacked configuration of memory cells.

### SUMMARY

Embodiments of the present disclosure are directed to a semiconductor device capable of improving power distribution efficiency, and a method for fabricating the semiconductor device.

These or other embodiments of the present disclosure are directed to a structure which directly supplies power to the transistors of a peripheral circuit unit in a stacked semiconductor device.

These or other embodiments of the present disclosure provide a semiconductor device which does not require a process of etching a high aspect ratio contact, thereby reducing the cost for fabricating a semiconductor device.

These or other embodiments of the present disclosure may provide a Direct Power Interconnection (DPI) structure which reduces power consumption and current resistance of a semiconductor device.

These or other embodiments of the present disclosure are directed a Back-Side Power Distribution Network (BSPDN) that may be used for a three-dimensional integrated circuit in which a memory cell array and a peripheral circuit are bonded by a wafer bonding process.

In accordance with an embodiment of the present disclosure, a semiconductor device includes: a first substrate; a memory cell array including memory cells that are vertically stacked over the first substrate; a second substrate including a front side facing the memory cell array and a back side at a higher level than the front side, and including a plurality of control circuits; a back-side power distribution network including a power interconnection that penetrates the second substrate and supplies power to the control circuits from the back side of the second substrate. The memory cell array vertically stacked over the first substrate is electrically connected to the plurality of control circuits of the second substrate by a bonding structure.

In accordance with another embodiment of the present disclosure, a method for fabricating a semiconductor device includes: forming a memory cell array over a first substrate; forming an array-side interconnection structure that is coupled to the memory cell array; forming a plurality of control circuits on a front side of a second substrate including a back side and the front side, and a buried power interconnection partially buried in the second substrate from the front side and coupled to the plurality of control circuits; forming a front-side interconnection structure coupled to the buried power interconnection; flipping the second substrate after forming the front-side interconnection structure; forming a back-side interconnection structure extending downward from the back side of the flipped second substrate and coupled to the buried power interconnection; and performing a bonding process for electrically connecting the memory cell array and the plurality of control circuits to each other.

### BRIEF DESCRIPTION OF THE DRAWINGS

FIG. 1 is a schematic cross-sectional view illustrating a semiconductor device in accordance with an embodiment of the present disclosure.

FIG. 2 is a schematic cross-sectional view illustrating a semiconductor device in accordance with another embodiment of the present disclosure.

FIG. 3 is a schematic cross-sectional view illustrating a semiconductor device according to a comparative example.

FIG. 4 is a schematic cross-sectional view illustrating a semiconductor device in accordance with another embodiment of the present disclosure.

FIG. 5A is a schematic perspective view illustrating a three-dimensional array of the memory cells shown in FIG. 4 according to an embodiment.

FIG. 5B is a schematic perspective view illustrating a memory cell shown in FIG. 4 according to an embodiment.

FIG. 5C is a schematic cross-sectional view illustrating the memory cell shown in FIG. 4 according to an embodiment.

FIG. 5D is a schematic plan view illustrating a switching element shown in FIGS. 5B and 5C according to an embodiment.

FIGS. 6 to 8 are side views illustrating a memory cell array in accordance with other embodiments of the present disclosure.

FIG. 9 illustrates another semiconductor device in accordance with another embodiment of the present disclosure.

FIGS. 10 and 11 illustrate an example of a direct power interconnection in accordance with another embodiment of the present disclosure.

FIGS. 12 to 23 illustrate an example of a method for fabricating the semiconductor device shown in FIG. 4.

FIG. 24 is a schematic cross-sectional view illustrating a semiconductor device in accordance with another embodiment of the present disclosure.

### DETAILED DESCRIPTION

Various embodiments of the present disclosure will be described below in more detail with reference to the accompanying drawings. The embodiments of the present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout the disclosure, like reference numerals refer to like parts throughout the various figures and embodiments of the present disclosure.

Hereinafter, the various embodiments of the present disclosure will be described in detail with reference to the attached drawings.

The drawings are not necessarily to scale and in some instances, proportions may have been exaggerated in order to clearly illustrate features of the embodiments. When a first layer is referred to as being ‘on’ a second layer or ‘on’ a substrate, it not only refers to a case where the first layer is formed directly on the second layer or the substrate but also a case where a third layer exists between the first layer and the second layer or the substrate.

The following embodiments of the present disclosure relate to a three-dimensional (3D) memory cell structure, which may increase the memory cell density and decrease the parasitic capacitance by vertically stacking memory cells.

The following embodiments of the present disclosure include a Back-Side Power Distribution Network (BSPDN) that may be used for a three-dimensional integrated circuit, in which a memory cell array and a peripheral circuit are bonded by a wafer bonding process.

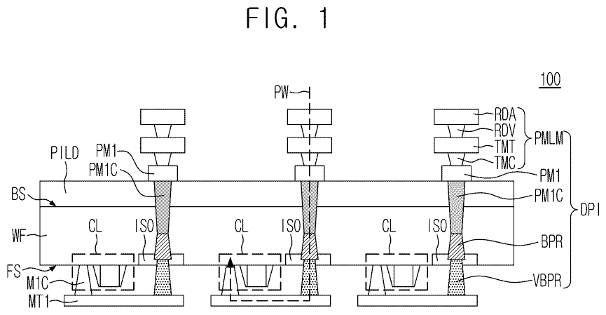

FIG. 1 is a schematic cross-sectional view illustrating a semiconductor device 100 in accordance with an embodiment of the present disclosure.

Referring to FIG. 1, the semiconductor device 100 may include a substrate WF including control circuits CL and isolation layers ISO between the control circuits CL, a metal contact plug M1C and a metal line MT1 coupled to the control circuits CL, and a direct power interconnection DPI coupled to the control circuits CL through the metal line MT1.

The direct power interconnection DPI may include a buried power rail BPR buried in the substrate WF, a buried power rail via VBPR coupled to a first surface of the buried power rail BPR, a post power via PM1C coupled to a second surface of the buried power rail BPR, a post power metal line PM1 coupled to the post power via PM1C, and a post-multi-level metal line PMLM coupled to the post power metal line PM1. The buried power rail BPR and the buried power rail via VBPR may be referred to as a buried power interconnection.

The substrate WF may include a front side FS and a back side BS. The substrate WF may be flipped over by wafer flipping such that the back side BS is disposed at a higher level than the front side FS. Therefore, the front side FS of the substrate WF may refer to a surface facing the metal line MT1, and the back side BS of the substrate WF may refer to a surface facing the post power metal line PM1. The lower level surface of the substrate WF may refer to the front side FS.

The isolation layers ISO may be formed in the substrate WF, and each of the isolation layers ISO may be disposed between an adjacent pair of the control circuits CL.

The first surface of the buried power rail BPR may be electrically connected to the metal contact plug MIC and the metal line MT1 through the buried power rail via VBPR, and the second surface of the buried power rail BPR may be electrically connected to the post power via PM1C and the post power metal line PM1.

The post-multi-level metal line PMLM may include a plurality of post metal lines TMT and RDA and a plurality of post vias TMC and RDV. The post via TMC may be electrically connected between the post power metal line PM1 and the post metal line TMT, and the post via RDV may be electrically connected between the post metal line TMT and the post metal line RDA. The post power via PM1C and the post power metal line PM1 may be electrically connected to the post-multi-level metal line PMLM. According to another embodiment of the present disclosure, the post power via PM1C and the post power metal line PM1 may be part of the post-multi-level metal line PMLM. In one embodiment, the post power via PM1C and the post power metal line PM1 may be formed while the post-multi-level metal line PMLM is formed.

A post inter-layer dielectric layer PILD may be formed on the back side BS of the substrate WF. The post inter-layer dielectric layer PILD may be disposed between the back side BS of the substrate WF and the post power metal line PM1. The post power via PM1C may extend toward or inside of the isolation layers ISO through the post inter-layer dielectric layer PILD and the substrate WF.

The post power via PM1C may have a low aspect ratio. The post power via PM1C may be referred to as a ‘Nano-Through Silicon Via NTSV’. The buried power rail via VBPR may be referred to as a via that lands on the buried power rail BPR, that is, a ‘via-to-buried power rail (Via-to-BPR) VBPR’.

The buried power rail via VBPR may extend from the front side FS of the substrate WF to the inside of the isolation layers ISO. The buried power rail BPR may extend from the front side FS of the substrate WF into the inside of the substrate WF through the isolation layers ISO. The buried power rail BPR may have a form that it is embedded inside of the substrate WF. The vertical structure of the post power via PM1C, the buried power rail BPR, and the buried power rail via VBPR may be a structure that penetrates the post inter-layer dielectric layer PILD, the substrate WF, and the isolation layers ISO.

Dielectric spacers may be disposed on the outer walls of the post power via PM1C and the buried power rail BPR, and thus, according to one embodiment the post power via PM1C and the buried power rail BPR may be electrically disconnected (or isolated) from the substrate WF.

The metal line MT1 and the metal contact plug M1C may be coupled to the control circuits CL. The metal line MT1 and the metal contact plug M1C may provide a path for transmitting power to the control circuits CL. The metal line MT1 and the metal contact plug M1C may be part of a multi-level metal line. The metal line MT1 may be spaced apart from the front side FS of the substrate WF.

The buried power rail via VBPR may be coupled to the metal line MT1 and the metal contact plug M1C. The metal contact plug M1C and the buried power rail via VBPR may be disposed at the same level. The control circuits CL may be electrically connected to the post-multi-level metal line PMLM through the metal contact plug M1C, the metal line MT1, the buried power rail via VBPR, the buried power rail BPR, the post power via PM1C, and the post power metal line PM1.

The direct power interconnection DPI may function to directly transmit power from the back side BS of the substrate WF. In other words, the combination of the post-multi-level metal line PMLM and the other layers of the direct power interconnection DPI may be referred to as a Back-Side Power Distribution Network (BSPDN) for transmitting power to the control circuits CL.

As described above, the semiconductor device 100 may include the metal line MT1 disposed at a lower level than the control circuits CL, the post-multi-level metal line PMLM disposed at a higher level than the control circuits CL, and the direct power interconnection DPI penetrating the substrate WF to be coupled to the control circuits CL through the metal line MT1 and the metal contact plug M1C.

In the semiconductor device 100, the direct power interconnection DPI may directly supply power to the control circuits CL through the metal line MT1 and the metal contact plug M1C by penetrating the substrate WF. As the direct power interconnection DPI penetrates the thin substrate WF, the path (see reference symbol ‘PW’) for transmitting power to the control circuits CL may become shorter. This, in turn, may reduce power consumption of the semiconductor device. The power transmission path PW may include the post-multi-level metal line PMLM, the post power metal line PM1, the post power via PM1C, the buried power rail BPR, the buried power rail via VBPR, the metal line MT1, and the metal contact plug M1C.

As described above, the method of supplying power to the control circuits CL in the semiconductor device 100 may be a top-down power supply from the post-multi-level metal line PMLM to the control circuits CL.

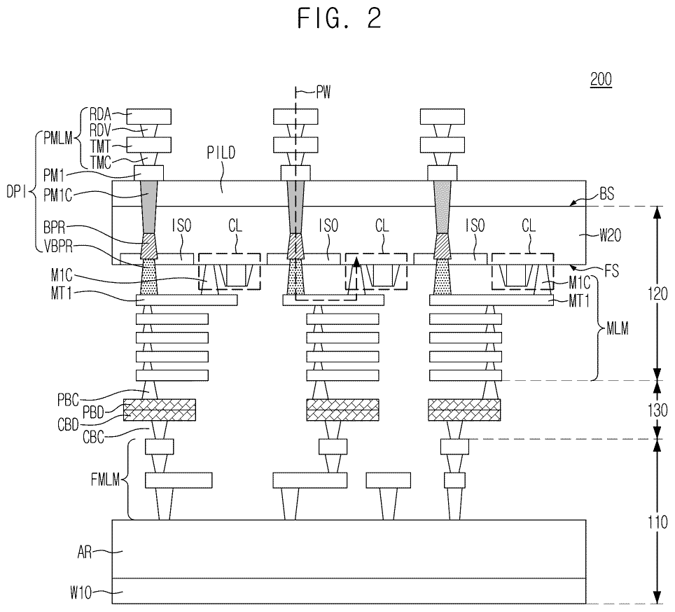

FIG. 2 is a schematic cross-sectional view illustrating a semiconductor device 200 in accordance with another embodiment of the present disclosure.

Referring to FIG. 2, the semiconductor device 200 may include a first semiconductor device 110, a second semiconductor device 120, a bonding structure 130 between the first semiconductor device 110 and the second semiconductor device 120, and a direct power interconnection DPI coupled to the second semiconductor device 120. As described below, the bonding structure 130 may improve the degree of integration of the semiconductor device 200. The direct power interconnection DPI may correspond, for example, to the direct power interconnection DPI shown in FIG. 1. The combination of the post-multi-level metal line PMLM and the other layers of the direct power interconnection DPI may form a Back-Side Power Distribution Network (BSPDN) for transmitting power to the control circuits CL.

The first semiconductor device 110 may include a first substrate W10, an array AR, and a front multi-level metal line FMLM. The array AR may be disposed over the first substrate W10, and the front multi-level metal line FMLM may be disposed over the array AR. The array AR may include a transistor array, a capacitor array, a memory cell array, or a combination thereof. The memory cell array may include a three-dimensional array of memory cells. For example, the memory cell array may include a buried gate-based Dynamic Random Access Memory (DRAM), a three-dimensional (3D) DRAM, a 3D NAND, a flash memory, a Spin Transfer Torque Random Access Memory (STTRAM), a Resistive Random Access Memory (RRAM), a Magnetic Random Access Memory (MRAM), a thyristor, a vertical gate-based DRAM, and the like. The front multi-level metal line FMLM may include a plurality of front metal lines and a plurality of front vias interleaved between the plurality of front metal lines. The front multi-level metal line FMLM may be referred to as an array-side interconnection structure.

The second semiconductor device 120 may include a second substrate W20 including a front side FS and a back side BS, a plurality of control circuits CL disposed on the front side FS of the second substrate W20, and a multi-level metal line MLM coupled to the control circuits CL. The back side BS of the second substrate W20 may be disposed at a higher level than the front side FS. The second substrate W20 may be flipped over by wafer flipping such that the back side BS is disposed at a higher level than the front side FS.

The multi-level metal line MLM may include a plurality of metal lines and a plurality of vias. The multi-level metal line MLM may include at least a metal line MT1 and a metal contact plug M1C. The metal line MT1 and the metal contact plug M1C may be respectively coupled to the control circuits CL. The metal line MT1 and the metal contact plug M1C may be a metal line and a metal contact for transmitting power. A plurality of isolation layers ISO may be formed in the second substrate W20, and the isolation layers ISO may be disposed between the control circuits CL. Each of the control circuits CL may include at least one transistor. The control circuits CL may include circuits for controlling the array AR of the first semiconductor device 110. Each transistor may include a gate, a gate spacer, and a sources/drain. The isolation layers ISO may have a Shallow Trench Isolation (STI) structure.

The bonding structure 130 may include a first bonding pad CBD coupled to the first semiconductor device 110, and a second bonding pad PBD coupled to the second semiconductor device 120. The wafer bonding structure 130 may further include a first bonding contact plug CBC and a second bonding contact plug PBC. The first bonding contact plug CBC may be coupled to (e.g., between) the front multi-level metal line FMLM and the first bonding pad CBD of the first semiconductor device 110. The second bonding contact plug PBC may be coupled to (e.g., between) the multi-level metal line MLM and the second bonding pad PBD of the second semiconductor device 120. Bonding dielectric layers may be disposed between the first bonding pads CBD of the same level, and the bonding dielectric layers may be disposed between the second bonding pads PBD of the same level.

The first bonding pad CBD and the second bonding pad PBD may be coupled by direct bonding or hybrid bonding. In one embodiment, direct bonding may include the case where the first bonding pad CBD and the second bonding pad PBD are directly bonded with each other, and may refer to, for example, metal-to-metal bonding. Hybrid bonding may include a combination of metal-to-metal bonding and dielectric-to-dielectric bonding. Dielectric-to-dielectric bonding may refer to bonding of bonding dielectric layers. Dielectric-to-dielectric bonding may include, for example, oxide-to-oxide bonding.

The direct power interconnection DPI may include a buried power rail BPR buried in the second substrate W20, a buried power rail via VBPR coupled to a first surface of the buried power rail BPR, a post power via PM1C coupled to a second surface of the buried power rail BPR, a post power metal line PM1 coupled to the post power via PM1C, and a post-multi-level metal line PMLM coupled to the post power metal line PM1. The first surface of the buried power rail BPR may be electrically connected to a metal contact plug M1C and a metal line MT1 of the multi-level metal line through the buried power rail via VBPR. The second surface of the buried power rail BPR may be electrically connected to the post power via PM1C and the power metal line PM1. The post-multi-level metal line PMLM may include a plurality of post metal lines TMT and RDA and a plurality of post vias TMC and RDV interleaved between the plurality of post metal lines TMT and RDA. In one embodiment, the post power via PM1C and the post power metal line PM1 may be considered to be a part of the post-multi-level metal line PMLM. The post-multi-level metal line PMLM may have a back side interconnection structure, and the multi-level metal line MLM may have a front side interconnection structure.

A post inter-layer dielectric layer PILD may be formed on the back side BS of the second substrate W20.

The buried power rail via VBPR may extend from the front side FS of the second substrate W20 to the inside of the isolation layers ISO. The buried power rail BPR may extend from the front side FS of the second substrate W20 to the inside of the second substrate W20 through the isolation layers ISO. The vertical structure of the post power via PM1C, the buried power rail BPR, and the buried power rail via VBPR may have a structure that penetrates the post inter-layer dielectric layer PILD, the second substrate W20, and the isolation layers ISO, respectively.

The buried power rail via VBPR may be coupled to the metal line MT1 and the metal contact plug M1C of the multi-level metal line MLM. The metal contact plug M1C and the buried power rail via VBPR may be disposed at the same level and, in some embodiments, may be formed by a same process.

The direct power interconnection DPI may function to directly transmit power from the back side BS of the second substrate W20 to the control circuit CL. In other words, the direct power interconnection DPI may be a Back-Side Power Distribution Network (BSPDN) for transmitting power to the control circuits CL.

As described above, the semiconductor device 200 may be a semiconductor device that includes the first semiconductor device 110, the bonding structure 130, and the second semiconductor device 120 that are sequentially stacked in this order. The control circuits CL of the second semiconductor device 120 may be coupled to the array AR of the first semiconductor device 110 through the bonding structure 130. Moreover, the array AR may be formed on substrate W10, instead of substrate W20, and the control circuits CL may be located in substrate W20. This allows a power transmission path (PW) to not pass through the array AR, which reduces complexity of the design, and may have the effect of reducing power consumption as described below with reference to the comparative example.

The semiconductor device 200 may directly supply power to the control circuits CL of the second semiconductor device 120 through the direct power interconnection DPI, the metal line MT1, and the metal contact plug M1C. Accordingly, the path (see reference symbol ‘PW’) for transmitting power to the control circuits CL may be shortened. The power transmission path PW may include the post-multi-level metal line PMLM, the power metal line PM1, the post power via PM1C, the buried power rail BPR, the buried power rail via VBPR, the metal line MT1, and the metal contact plug M1C.

As above, the method of supplying power to the control circuits CL in the semiconductor device 200 may be a top-down power supply from the post-multi-level metal line PMLM to the control circuits CL.

The first semiconductor device 110 and the second semiconductor device 120 may be bonded with each other by a wafer bonding process. In other words, the first semiconductor device 110 and the second semiconductor device 120 may be bonded with each other by the bonding structure 130. The bonding structure 130 may improve the integration degree, such as overcoming process limitations and maximizing net die.

Since the Direct Power Interconnection (DPI) penetrating the second substrate W20 is formed, when the wafer bonding process is applied, power consumption of the semiconductor device 200 may be decreased by a predetermined amount, e.g., approximately 15% or more. Further, the current resistance of the semiconductor device 200 may be reduced by a predetermined amount, e.g., approximately 20% or more.

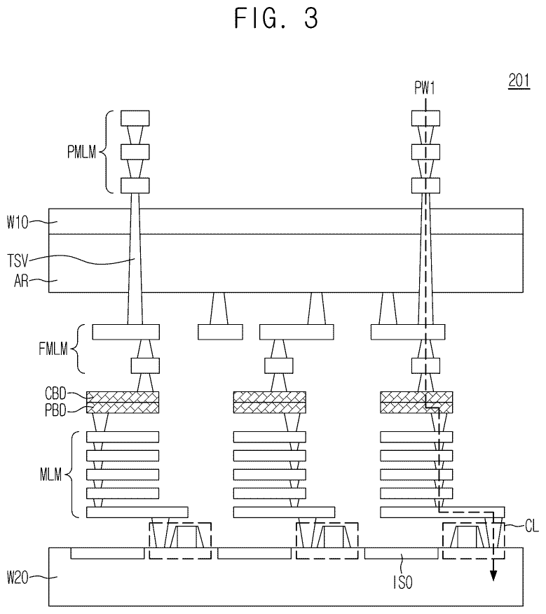

FIG. 3 is a schematic cross-sectional view illustrating a semiconductor device 201 according to a comparative example.

Referring to FIG. 3, the semiconductor device 201 according to the comparative example may include a first substrate W10 where an array AR and a front multi-level metal line FMLM are formed, a second substrate W20 where control circuits CL and a multi-level metal line MLM are formed, bonding structures CBD and PBD between the front multi-level metal line FMLM and the multi-level metal line MLM, and a post-multi-level metal line PMLM at a higher level than the first substrate W10. The array AR may include, for example, a memory cell array. In the semiconductor device 201 of the comparative example, the first substrate W10 where the array AR and the front multi-level metal line FMLM are formed may be flipped over. In other words, the first substrate W10 may be disposed at a higher level than the second substrate W20.

The semiconductor device 201 of the comparative example may supply power to the control circuits CL through the post-multi-level metal line PMLM, and needs a through silicon via TSV of a high aspect ratio penetrating the array AR to interconnect the control circuits CL and the post-multi-level metal line PMLM to each other. Since power is supplied to the control circuits CL through the through silicon via TSV of a high aspect ratio, the bonding structures CBD and PBD, and a plurality of multi-level metal lines MLM, power consumption and resistance may be increased.

As described, the semiconductor device 201 of the comparative example may need a high aspect ratio contact etching (HARC) process for the first substrate W10 and the array AR to form a through silicon via TSV of a high aspect ratio penetrating the array AR. Therefore, the increase in the number of the memory cells that are stacked in the array AR may inevitably increase the production cost and the technical difficulty. Further, since the semiconductor device 201 of the comparative example has a long power transmission path PW1 due to the through silicon via TSV of a high aspect ratio, the power consumption and production cost may be increased.

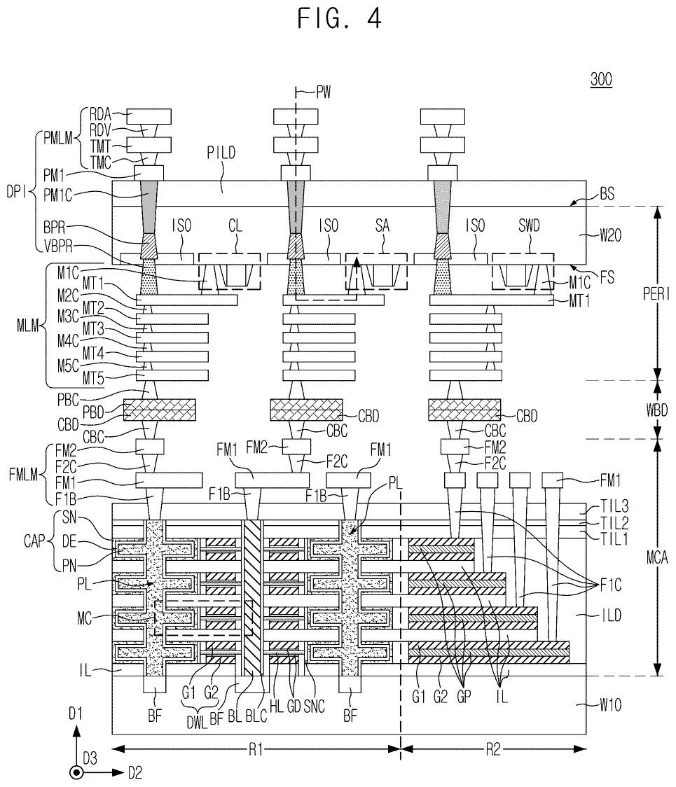

FIG. 4 is a schematic cross-sectional view illustrating a semiconductor device 300 in accordance with another embodiment of the present disclosure. For example, FIG. 4 may illustrate a more detailed example of the semiconductor device 200 shown in FIG. 2.

Referring to FIG. 4, the semiconductor device 300 may include a memory cell array MCA, a peripheral circuit PERI, a bonding structure WBD between the memory cell array MCA and the peripheral circuit PERI, and a direct power interconnection DPI coupled to, or included in, the peripheral circuit PERI. The direct power interconnected structure DPI may be the ones shown, for example, in FIG. 1 or 2.

The memory cell array MCA may be disposed over a first substrate W10. The memory cell array MCA may include a three-dimensional array of memory cells MC and a front multi-level metal line FMLM. The three-dimensional array of the memory cells MC may be disposed over the first substrate W10, and the front multi-level metal line FMLM may be disposed over the three-dimensional array of the memory cells MC. The memory cell array MCA may include a first region R1 and a second region R2. The first region R1 may be a region where memory cells MC are formed, and the second region R2 may be a region where cell contact plugs coupled to the memory cells MC are formed. The second region R2 may have a stepped structure.

Each memory cell MC may include a first conductive line BL, a switching element TR, and a data storage element CAP. The three-dimensional array of the memory cells MC may include a column array of memory cells MC and a row array of memory cells MC. The column array of the memory cells MC may have a plurality of memory cells MC that are stacked in a first direction D1, and the row array of the memory cells MC may have a plurality of memory cells MC that are horizontally disposed in a second direction D2 and a third direction D3. The memory cell array MCA may have a mirror-type structure in which two memory cells MC share a first conductive line BL. According to another embodiment of the present disclosure, the memory cell array MCA may further include a mirror-type structure in which two memory cells MC share a data storage element CAP. The multi-level metal line MLM may include a plurality of metal lines MT1, MT2, MT3, MT4 and MT5 and a plurality of metal contact plugs M1C, M2C, M3C, M4C and M5C.

The memory cell array MCA may include first to third hard mask layers TIL1, TIL2 and TIL3. The upper surfaces of the first conductive line BL and the common plate PL may be disposed at the same level as the upper surface of the second hard mask layer TIL2. The front multi-level metal line FMLM of the memory cell array MCA may include first front vias F1B, first front metal lines FM1, second front vias F2C, and second front metal lines FM2. The first front vias F1B may penetrate the third hard mask layer TIL3 to be coupled to the first conductive line BL and the common plate PL, respectively. The second front metal lines FM2 may be coupled to first bonding pads CBD through to first bonding contact plugs CBC.

In the second region R2 of the memory cell array MCA, each step of the stepped structure may include an upper horizontal line G1, a lower horizontal line G2, and a pad GP between the upper horizontal line G1 and the lower horizontal line G2. Inter-cell dielectric layers IL may be disposed between the steps. The inter-cell dielectric layers IL may include, for example, silicon oxide. The inter-cell dielectric layers IL may be referred to as horizontal inter-cell dielectric layers. Each of the upper horizontal lines G1 of the stepped structure may be coupled to first front metal lines FM1 through corresponding ones of the first front contact plugs F1C. The first front contact plugs F1C may be referred to as cell contact plugs. The first front contact plugs F1C may penetrate the first to third hard mask layers TIL1, TIL2 and TIL3 and the inter-layer dielectric layer ILD.

A buffer layer BF may be disposed on the bottom surface of the first conductive line BL and the bottom surface of the common plate PL, respectively.

The peripheral circuit PERI may include at least one control circuit CL, SA and SWD for driving the memory cell array MCA. The at least one control circuit CL, SA and SWD of the peripheral circuit PERI may include an N-channel transistor, a P-channel transistor, a CMOS circuit, or a combination thereof. The at least one control circuit CL, SA and SWD of the peripheral circuit PERI may include one or more additional circuits, e.g., an address decoder circuit, a read circuit, a write circuit, and the like. The at least one control circuit CL, SA and SWD of the peripheral circuit PERI may include, for example, a planar channel transistor, a recess channel transistor, a buried gate transistor, and/or a fin channel transistor (FinFET). The control circuit CL, SA and SWD may be referred to as a peripheral transistor.

For example, the peripheral circuit PERI may include a common plate control circuit CL, sub-word line drivers SWD, and a sense amplifier SA. A first conductive line BL of the memory cell array MCA may be coupled to the sense amplifier SA, and second conductive lines DWL may be coupled to the sub-word line drivers SWD. Common plates PL may be coupled to a common plate control circuit CL. Each of the transistors for the common plate control circuit CL, the sub-word line drivers SWD, and the sense amplifier SA may include a gate, a gate spacer, and a sources/drain. The isolation layers ISO may be a Shallow Trench Isolation (STI) structure.

The peripheral circuit PERI may be formed over the second substrate W20 and may further include a multi-level metal lines MLM coupled to respective ones of the control circuits CL, SA and SWD. Each multi-level metal line MLM may include a plurality of metal lines MT1 to MT5 and a plurality of metal contact plugs M1C to M5C, some of which are interleaved between the plurality of metal lines MT1 to MT5. Each multi-level metal line MLM may include at least one first level metal line MT1 and at least one first level metal contact plug M1C. The first level metal line MT1 and the first level metal contact plug M1C may be coupled to corresponding ones of the control circuits CL, SA and SWD. A plurality of isolation layers ISO may be formed in the second substrate W20. Each isolation layer ISO may be disposed between an adjacent pair of the control circuits CL, SA and SWD. The isolation layers ISO may have a Shallow Trench Isolation (STI) structure.

The second substrate W20 may include a front side FS and a back side BS, and the back side BS of the second substrate W20 may be disposed at a higher level than the front side FS. The second substrate W20 may be flipped over by wafer flipping such that the back side BS is disposed at a higher level than the front side FS. The first level metal line MT1 and the first level metal contact plug M1C of the multi-level metal line MLM may be included in a power transmission path PW.

The bonding structure WBD may include a first bonding pad CBD that is coupled to the memory cell array MCA, and a second bonding pad PBD that is coupled to the peripheral circuit PERI. The bonding structure WBD may further include a first bonding contact plug CBC and a second bonding contact plug PBC. The first bonding contact plug CBC may be coupled between the front multi-level metal line FMLM of the memory cell array MCA, and the first bonding pad CBD. The second bonding contact plug PBC may be coupled between a corresponding one of the multi-level metal lines MLM of the peripheral circuit PERI, and the second bonding pad PBD. Bonding dielectric layers may be disposed between the first bonding pads CBD of the same level, and bonding dielectric layers may be disposed between the second bonding pads PBD of the same level. The first bonding pad CBD and the second bonding pad PBD may be coupled by direct bonding or hybrid bonding. The direct bonding may include a case where the first bonding pad CBD and the second bonding pad PBD are directly bonded with each other, and may refer to, for example, metal-to-metal bonding. The hybrid bonding may include a combination of metal-to-metal bonding and dielectric-to-dielectric bonding. The dielectric-to-dielectric-layer bonding may refer to bonding of the bonding dielectric layers. The dielectric layer-to-dielectric layer bonding may include, for example, oxide-to-oxide bonding.

The direct power interconnection DPI may include a buried power rail BPR buried in the second substrate W20, a buried power rail via VBPR coupled to a first surface of the buried power rail BPR, a post power via PM1C coupled to a second surface of the buried power rail BPR, a post power metal line PM1 coupled to the post power via PM1C, and a post-multi-level metal line PMLM coupled to the post power metal line PM1. The first surface of the buried power rail BPR may be electrically connected to the first level metal contact plug MIC and the first level metal line MT1 of the multi-level metal line, and the second surface of the buried power rail BPR may be electrically connected to the post power via PM1C and the post power metal line PM1. The post-multi-level metal line PMLM may include a plurality of post metal lines TMT and RDA and a plurality of post vias TMC and RDV interleaved between the plurality of post metal lines TMT and RDA. The post power via PM1C and the post power metal line PM1 may be part of the post-multi-level metal line PMLM.

A post inter-layer dielectric layer PILD may be formed on the back side BS of the second substrate W20.

Each buried power rail via VBPR may extend from the inside of a corresponding one of the isolation layers ISO and may extend from the front side FS of the second substrate W20. The buried power rail BPR may extend inside the second substrate W20 at a location adjacent to the front side FS of the second substrate W20. The buried power rail BPR may at least partially extend into a corresponding one of the isolation layers ISO. The vertical structure of the post power via PM1C, the buried power rail BPR, and the buried power rail via VBPR may be a structure that penetrates the post inter-layer dielectric layer PILD, the second substrate W20, and the isolation layers ISO.

The buried power rail via VBPR may be coupled to the first level metal line MT1 and the first level metal contact plug M1C of the multi-level metal line MLM. The first level metal contact plug M1C and the buried power rail via VBPR may be disposed at the same level.

The direct power interconnection DPI may function to directly transmit power from the back side BS of the second substrate W20. In other words, the direct power interconnection DPI may be a Back-Side Power Distribution Network (BSPDN) for transmitting power to the control circuits CL, SA and SWD.

As described above, the semiconductor device 300 may have a POC (PERI-Over-Cell array) structure in which the memory cell array MCA, the bonding structure WBD, and the peripheral circuit PERI are sequentially stacked in this order. The control circuits CL, SA and SWD of the peripheral circuit PERI may be electrically connected to the memory cell array MCA through the bonding structure WBD.

In the semiconductor device 300, power may be supplied to the post-multi-level metal line PMLM (for example, from a power supply or power management circuit), and the power may be directly supplied from the post-multi-level metal line PMLM to the control circuits CL, SA and SWD of the peripheral circuit PERI through the direct power interconnection DPI, the first level metal line MT1, and the first level metal contact plug M1C. Accordingly, the path (see reference symbol ‘PW’) for transmitting power to the control circuits CL, SA and SWD may be shortened, which may reduce power consumption. The power transmission path PW may include the post-multi-level metal line PMLM, the power metal line PM1, the post power via PM1C, the buried power rail BPR, the buried power rail via VBPR, the first level metal line MT1, and the first level metal contact plug M1C.

As described above, the method of supplying power to the control circuits CL, SA and SWD in the semiconductor device 300 may be a top-down power supply from the post-multi-level metal line PMLM to the control circuits CL, SA and SWD.

The memory cell array MCA and the peripheral circuit PERI may be bonded with each other by a wafer bonding process. In other words, the memory cell array MCA and the peripheral circuit PERI may be bonded with each other by the bonding structure WBD. The bonding structure WBD may improve the degree of integration of the semiconductor device 300, such as overcoming process limitations and maximizing net die.

Since the Direct Power Interconnection DPI penetrating the second substrate W20 is formed, when the wafer bonding process is applied, the power consumption of the semiconductor device 300 may be decreased, for example, by approximately 15% or more. Further, the current resistance of the semiconductor device 300 may be decreased, for example, by approximately 20% or more.

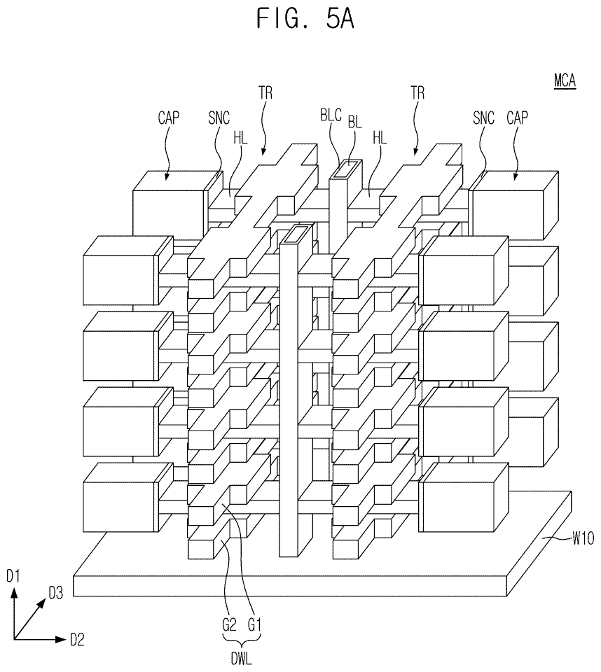

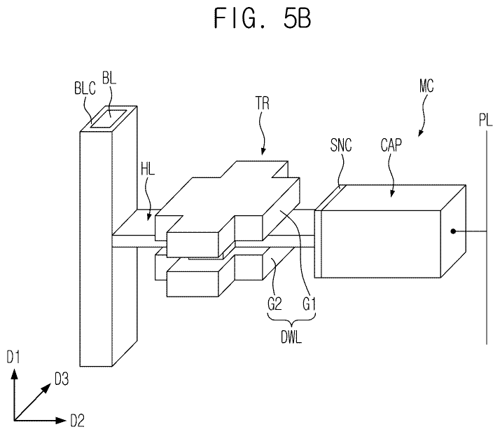

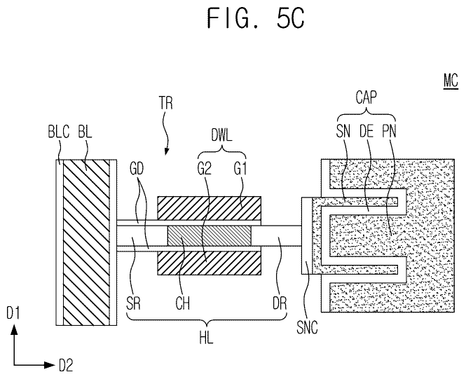

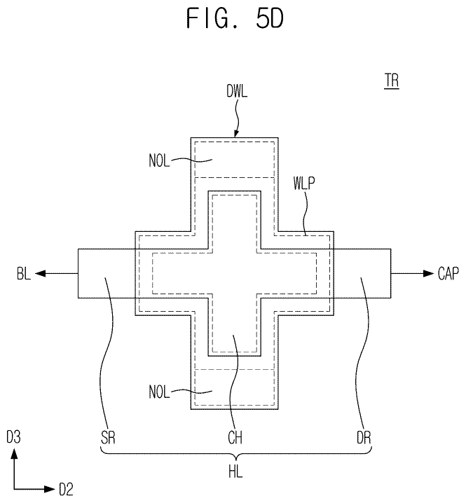

FIG. 5A is a schematic perspective view illustrating a three-dimensional array of memory cells shown in FIG. 4. FIG. 5B is a schematic perspective view illustrating a memory cell shown in FIG. 4. FIG. 5C is a schematic cross-sectional view illustrating the memory cell shown in FIG. 4. FIG. 5D is a schematic plan view illustrating a switching element show in FIGS. 5B and 5C.

Referring to FIGS. 5A to 5D, the memory cell array MCA may include a three-dimensional array of memory cells MC, and each memory cell MC may include a first conductive line BL, a switching element TR, and a data storage element CAP.

The first conductive line BL may be vertically oriented in the first direction D1. The first conductive line BL may include a bit line. The first conductive line BL may be referred to as a vertical conductive line, a vertically-oriented bit line, a vertically-extending bit line, or a pillar-shaped bit line. The first conductive line BL may include a conductive material. The first conductive line BL may include a silicon-based material, a metal-based material, or a combination thereof. The first conductive line BL may include polysilicon, a metal, a metal nitride, a metal silicide, or a combination thereof. The first conductive line BL may include polysilicon, titanium nitride, tungsten, or a combination thereof. For example, the first conductive line BL may include a titanium nitride/tungsten stack (TiN/W) in which titanium nitride and tungsten are sequentially stacked.

The switching element TR may perform the function of controlling a voltage (or current) supply to the data storage element CAP in a data write operation and a data read operation for the data storage element CAP. In one embodiment, the switching element TR may include a nanosheet HL, a nanosheet dielectric layer GD, and a second conductive line DWL. The second conductive line DWL may include a horizontal conductive line or a horizontal word line, and the nanosheet HL may include an active layer. The switching element TR may include a transistor. In this case, the second conductive line DWL may function as a gate electrode. The switching element TR may also be referred to as a cell transistor, a nanosheet transistor, an access element, or a selection element. The second conductive line DWL may be referred to as a horizontal gate electrode or a horizontal word line.

The nanosheet HL may extend in the second direction D2 intersecting with the first direction D1. The second conductive line DWL may extend in the third direction D3 intersecting with the first direction D1 and the second direction D2. The first direction D1 may be a vertical direction, and the second direction D2 may be a first horizontal direction, and the third direction D3 may be a second horizontal direction. The nanosheet HL may extend in the first horizontal direction (e.g., the second direction D2), and the second conductive line DWL may extend in the second horizontal direction (e.g., the third direction D3). The nanosheet HL may be referred to as a ‘horizontal layer’.

The nanosheet HL may include a channel CH, a first doped region SR between the channel CH and the first conductive line BL, and a second doped region DR between the channel CH and the data storage element CAP. The first doped region SR may serve as one of a drain or source, and the second doped region DR may serve as the other one of the drain or source. The first doped region SR may be coupled to the first conductive line BL, and the second doped region DR may be coupled to the data storage element CAP. The height of the second doped region DR in the first direction D1 may be larger than the height of the channel CH in the first direction D1. The length of the second doped region DR in the second direction D2 may be smaller than the length of the channel CH in the second direction D2. The lengths of the first doped region SR, the channel CH, and the second doped region DR in the third direction D3 may be the same.

The nanosheet HL may be horizontally oriented from the first conductive line BL in the second direction D2. The second conductive line DWL may have a dual-gate structure. For example, the second conductive line DWL may include an upper horizontal (gate) line G1 and a lower horizontal (gate) line G2 that are facing each other with the nanosheet HL interposed therebetween. The nanosheet dielectric layer GD may be formed on the upper surface and the lower surface of the nanosheet HL. The upper horizontal line G1 may be disposed in the upper portion of the nanosheet HL, and the lower horizontal line G2 may be disposed in the lower portion of the nanosheet HL. The second conductive line DWL may include a pair of the upper horizontal line G1 and the lower horizontal line G2.

In the second conductive line DWL, the same driving (e.g., gate) voltage may be applied to the upper horizontal line G1 and the lower horizontal line G2. For example, the upper horizontal line G1 and the lower horizontal line G2 may form a pair and may be coupled to one memory cell MC. According to another embodiment of the present disclosure, different driving voltages may be applied to the upper horizontal line G1 and the lower horizontal line G2. In this case, one horizontal line among the upper horizontal line G1 and the lower horizontal line G2 may serve as a back gate or a shield gate. According to another embodiment of the present disclosure, the second conductive line DWL may have a gate-all-around structure (GAA).

Referring to FIG. 5D, each of the upper horizontal line G1 and the lower horizontal line G2 may have a width in the second direction D2 (for example, the width of an overlapping portion that overlaps with the nanosheet HL) which is larger than the width of a portion that does not overlap with the nanosheet HL, which is a channel non-overlapping portion NOL. Due to the difference in the widths, the second conductive line DWL may have a notch-shaped sidewall. The second conductive line DWL may include a channel overlapping portion WLP and a channel non-overlapping portion NOL. The channel overlapping portion WLP may refer to a portion that overlaps with the channel CH of the nanosheet HL, and the channel non-overlapping portion NOL may refer to a portion that does not overlap with the nanosheet HL. The channel overlapping portion WLP may have a predetermined shape, such as, but not limited to, a cross shape or a rhombus shape. From the perspective of a top view, the nanosheet HL may have a cross shape or a rhombus shape. According to another embodiment of the present disclosure, the side surfaces of the nanosheet HL may have a bended shape or a rounded shape.

The nanosheet HL may include a semiconductor material. For example, the nanosheet HL may include polysilicon, monocrystalline silicon, germanium, or silicon-germanium. According to another embodiment of the present disclosure, the nanosheet HL may include an oxide semiconductor material. For example, the oxide semiconductor material may include IGZO (Indium Gallium Zinc Oxide), InSnZnO, ZnSnO, or a combination thereof. According to another embodiment of the present disclosure, the nanosheet HL may include a conductive metal oxide. According to another embodiment of the present disclosure, the nanosheet HL may include a two-dimensional material, for example, MoS, WS₂, or MoSe₂.

When the nanosheet HL is an oxide semiconductor material, the channel CH may be formed of an oxide semiconductor material, and the first and second doped regions SR and DR may be omitted. The nanosheet HL may also be referred to as an active layer or a thin-body.

The upper and lower surfaces of the nanosheet HL may have a flat surface. For example, the upper surface and the lower surface of the nanosheet HL may be parallel to each other in the second direction D2.

The channel CH of the nanosheet HL and the channel overlapping portion WLP of the second conductive line DWL may overlap with each other. The channel CH of the nanosheet HL may have a predetermined shape, e.g., a shape which corresponds to the shape of the channel overlapping portion WLP, such as, but not limited to, a cross shape or a rhombus shape. The size of the channel overlapping portion WLP of the second conductive line DWL may be larger than the size of the channel CH in at least one direction. The channel overlapping portion WLP of the second conductive line DWL may fully overlap with the channel CH.

The first doped region SR and the second doped region DR may be doped with impurities of the same conductive type. The first doped region SR and the second doped region DR may be doped with an N-type conductive impurity or a P-type conductive impurity. The first doped region SR and the second doped region DR may include at least one impurity selected among arsenic (As), phosphorus (P), boron (B), indium (In), and combinations thereof. The first doped region SR may be coupled to the first conductive line BL, and the second doped region DR may be coupled to the data storage element CAP. The first and second doped regions SR and DR may be referred to as first and second source/drain regions.

The nanosheet dielectric layer GD may be disposed between the nanosheet HL and the second conductive line DWL. The nanosheet dielectric layer GD may be referred to as a ‘gate dielectric layer’ or a channel-side dielectric layer. The nanosheet dielectric layer GD may include silicon oxide, silicon nitride, a metal oxide, a metal oxide nitride, a metal silicate, a high-k material, a ferroelectric material, an anti-ferroelectric material, or a combination thereof. The nanosheet dielectric layer GD may include SiO₂, Si₃N₄, HfO₂, Al₂O₃, ZrO₂, AlON, HfON, HfSiO, HfSiON, HfZrO, or a combination thereof. The nanosheet dielectric layer GD may be formed by a thermal oxidation process of a semiconductor material.

The second conductive line WL may include a metal-based material, a semiconductor material, or a combination thereof. The second conductive line WL may include molybdenum, molybdenum nitride, ruthenium, titanium nitride, tungsten, polysilicon, or a combination thereof. For example, the second conductive line WL may include a TiN/W stack in which titanium nitride and tungsten are sequentially stacked. The second conductive line WL may include an N-type work function material or a P-type work function material. The N-type work function material may have a predetermined low work function (e.g., of approximately 4.5 eV or lower), and the P-type work function material may have a predetermined high work function, e.g., of approximately 4.5 eV or higher. The second conductive line WL may include a stack of a low work function material and a high work function material.

The data storage element CAP may include a memory element, such as a capacitor. The data storage element CAP may be horizontally disposed from the switching element TR in the second direction D2. The data storage element CAP may include a first electrode SN extending horizontally from a horizontal layer HL in the second direction D2. The data storage element CAP may further include a second electrode PN over the first electrode SN, and a dielectric layer DE between the first electrode SN and the second electrode PN. The first electrode SN, the dielectric layer DE, and the second electrode PN may be horizontally disposed in the second direction D2.

The first electrode SN, the second electrode PN, and the dielectric layer DE may be disposed to have different patterns, as shown in FIG. 5C. For example, the first electrode SN may include an inner space and a plurality of outer surfaces, and the inner space of the first electrode SN may include a plurality of inner surfaces. The outer surfaces of the first electrode SN may include a vertical outer surface and a plurality of horizontal outer surfaces coupled to the vertical outer surface. The vertical outer surface of the first electrode SN may extend vertically in the first direction D1, and the horizontal outer surfaces of the first electrode SN may extend horizontally in the second direction D2 or the third direction D3. The inner space of the first electrode SN may be a three-dimensional space. The dielectric layer DE may conformally cover the inner surfaces and the outer surfaces of the first electrode SN. The second electrode PN may be disposed at least partially in the inner space of the first electrode SN over the dielectric layer DE. One or more of the outer surfaces of the first electrode SN may be electrically connected to the second doped region DR of the horizontal layer HL. The second electrode PN of the data storage element CAP may be coupled to a common plate PL (see, e.g., FIG. 5B).

The data storage element CAP may have a three-dimensional structure. The first electrode SN may have a three-dimensional structure, and the first electrode SN of the three-dimensional structure may be a horizontal three-dimensional structure which is oriented in the second direction D2. As an example of the three-dimensional structure, the first electrode SN may have, for example, a cylinder shape. The cylinder shape of the first electrode SN may include cylinder inner surfaces and cylinder outer surfaces. One or more of the cylinder outer surfaces of the first electrode SN may be electrically connected to the second doped region DR of the horizontal layer HL. The dielectric layer DE and the second electrode PN may be disposed on the cylinder inner surfaces of the first electrode SN.

According to another embodiment of the present disclosure, the first electrode SN may have a shape different from a cylinder shape, e.g., a pillar shape or a pylinder shape. The pylinder shape may refer to a structure in which a pillar shape and a cylinder shape are merged.

The first electrode SN and the second electrode PN may include a metal, a noble metal, a metal nitride, a conductive metal oxide, a conductive noble metal oxide, a metal carbide, a metal silicide, or a combination thereof. For example, the first electrode SN and the second electrode PN may include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum nitride (MoN), molybdenum oxide (MoO), a titanium nitride/tungsten (TiN/W) stack, a tungsten nitride/tungsten (WN/W) stack, a titanium silicon nitride/titanium nitride (TiSiN/TiN) stack, a titanium nitride/titanium silicon nitride (TiN/TiSiN) stack, or a combination thereof. The second electrode PN may also include a combination of a metal-based material and a silicon-based material. For example, the second electrode PN may be a stack of titanium nitride/silicon germanium/tungsten nitride (TiN/SiGe/WN). In the titanium nitride/silicon germanium/tungsten nitride (TiN/SiGe/WN) stack, silicon germanium may be a gap-fill material that fills the inside of the first electrode SN, and titanium nitride (TiN) may serve as the second electrode PN of the data storage element CAP, and tungsten nitride may be a low-resistance material. According to another embodiment of the present disclosure, the second electrode PN may include titanium nitride, tungsten, and polysilicon that are stacked in the mentioned order.

The dielectric layer DE may be referred to as a capacitor dielectric layer or a memory layer. The dielectric layer DE may include silicon oxide, silicon nitride, a high-k material, a perovskite material, or a combination thereof. The dielectric layer DE may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃). According to another embodiment of the present disclosure, the dielectric layer DE may be formed of a composite layer including two or more layers of the aforementioned high-k materials.

The dielectric layer DE may include zirconium-based oxide. The dielectric layer DE may have a stacked structure including zirconium oxide (ZrO₂). The dielectric layer DE may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked over zirconium oxide (ZrO₂). The ZAZ stack may have a structure in which zirconium oxide (ZrO₂), aluminum oxide (Al₂O₃), and zirconium oxide (ZrO₂) are sequentially stacked. The ZA stack and the ZAZ stack may be referred to as a zirconium oxide (ZrO₂)-based layer. According to another embodiment of the present disclosure, the dielectric layer DE may be formed of hafnium (Hf)-based oxide. The dielectric layer DE may have a stacked structure including hafnium oxide (HfO₂). The dielectric layer DE may include an HA (HfO₂/Al₂O₃) stack or a HAH (HfO₂/Al₂O₃/HfO₂) stack. The HA stack may have a structure in which aluminum oxide (Al₂O₃) is stacked over hafnium oxide (HfO₂). The HAH stack may have a structure in which hafnium oxide (HfO₂), aluminum oxide (Al₂O₃), and hafnium oxide (HfO₂) are sequentially stacked. The HA stack and the HAH stack may be referred to as a hafnium oxide-based layer (HfO₂). In the ZA stack, the ZAZ stack, the HA stack, and the HAH stack, aluminum oxide (Al₂O₃) may have a larger band gap energy than zirconium oxide (ZrO₂) and hafnium oxide (HfO₂). Aluminum oxide (Al₂O₃) may have a smaller dielectric constant than zirconium oxide (ZrO₂) and hafnium oxide (HfO₂). Therefore, the dielectric layer DE may include a stack of a high-k material and a high-band gap material whose band gap energy is larger than that of the high-k material. Other than aluminum oxide (Al₂O₃), the dielectric layer DE may include silicon oxide (SiO₂) as another high-band gap material. The dielectric layer DE may suppress leakage current by including a high band gap material. The high band gap material may be thinner than the high-k material.

According to another embodiment of the present disclosure, the dielectric layer DE may include a stacked structure in which high-k materials and high-band gap materials are alternately stacked. For example, the dielectric layer DE may include a ZA (ZrO₂/Al₂O₃) stack, a ZAZ (ZrO₂/Al₂O₃/ZrO₂) stack, a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HA (HfO₂/Al₂O₃) stack, a HAH (HfO₂/Al₂O₃/HfO₂) stack, a HAHA (HfO₂/Al₂O₃/HfO₂/Al₂O₃) stack, a HAHAH (HfO₂/Al₂O₃/HfO₂/Al₂O₃/HfO₂) stack, a HZAZH (HfO₂/ZrO₂/Al₂O₃/ZrO₂/HfO₂) stack, a ZHZAZHZ (ZrO₂/HfO₂/ZrO₂/Al₂O₃/ZrO₂/HfO₂/ZrO₂) stack, a HZHZ (HfO₂/ZrO₂/HfO₂/ZrO₂) stack, an AHZAZHA (Al₂O₃/HfO₂/ZrO₂/Al₂O₃/ZrO₂/HfO₂/Al₂O₃) stack, or an AHZAHZA (Al₂O₃/HfO₂/ZrO₂/Al₂O₃/HfO₂/ZrO₂/Al₂O₃) stack. In the above stacked structure, the aluminum oxide (Al₂O₃) may be thinner than the zirconium oxide (ZrO₂) and the hafnium oxide (HfO₂).

According to another embodiment of the present disclosure, the dielectric layer DE may include a high-k material and a high-band gap material. The dielectric layer DE may have a laminated structure in which a plurality of high-k materials and a plurality of high-band gap materials are stacked, or an intermixing structure in which a high-k material and a high-band gap material are intermixed.

According to another embodiment of the present disclosure, the dielectric layer DE may include a ferroelectric material, an anti-ferroelectric material, or a combination thereof. For example, the dielectric layer DE may include HfZrO.

According to another embodiment of the present disclosure, the dielectric layer DE may include a combination of a high-k material and a ferroelectric material, a combination of a high-k material and an anti-ferroelectric material, a combination of a high-k material or a ferroelectric material and an anti-ferroelectric material.

According to another embodiment of the present disclosure, a lower interface control layer (e.g., for improving leakage current) may be formed between the first electrode SN and the dielectric layer DE, and an upper interface control layer may be formed between the second electrode PN and the dielectric layer DE. The lower interface control layer and the upper interface control layer may include titanium oxide (TiO₂), tantalum oxide (Ta₂O₅), niobium, niobium oxide (Nb₂O₅), niobium nitride (NbN), niobium oxynitride (NbON), or a combination thereof. The lower interface control layer and the upper interface control layer may include a single-layer structure or a double-layer structure. For example, the upper interface control layer may include a stack of titanium oxide (TiO₂) and niobium oxide (NbO).

The data storage element CAP may include a three-dimensional capacitor. The data storage element CAP may include a MIM (metal-insulator-metal) capacitor. The data storage element CAP may also be replaced with another data storage material. For example, the data storage material may be a thyristor, a phase change material, a Magnetic Tunnel Junction (MTJ), or a variable resistance material.

For example, the memory cell MC may include a thyristor, and the first conductive line BL may be a cathode line, and the data storage element CAP may be replaced with an anode line. Accordingly, the nanosheet HL may include a plurality (e.g., four) semiconductor layers that are stacked in the second direction D2. The thyristor may include a first diode and a second diode that are coupled in series. When a forward bias of the same voltage is applied to the thyristor, the thyristor may have a high conductance state, in which a large amount of current flows, or a low conductance state, in which a relatively small amount of current flows or no current flows. The memory cell MC may store a voltage which has a logical ‘1’ state and a voltage which has a logical ‘0’ state, respectively, according to the high conductance state and the low conductance state of the thyristor.

Referring back to FIGS. 5B and 5C, the memory cell MC may further include a first contact node BLC and a second contact node SNC. The first contact node BLC may surround the outer wall of the first conductive line BL. The second contact node SNC may be disposed between the nanosheet HL and the first electrode SN of the data storage element CAP. The first contact node BLC may include a metal-based material or a semiconductor material. The second contact node SNC may include a metal-based material or a semiconductor material. For example, the first and second contact nodes BLC and SNC may include titanium, titanium nitride, tungsten, or a combination thereof. Further, the first and second contact nodes BLC and SNC may include doped polysilicon, and the first doped region SR and the second doped region DR may include the impurities diffused from the first contact node BLC and the second contact node SNC, respectively.

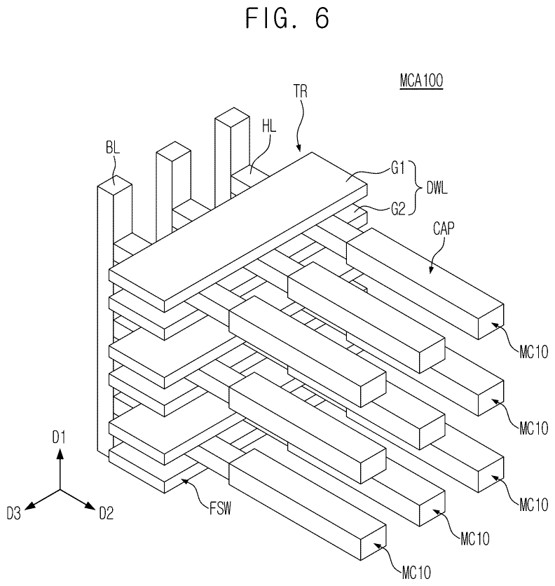

FIGS. 6 to 8 are side views illustrating a memory cell array in accordance with other embodiments of the present disclosure. The memory cell arrays MCA100, MCA200 and MCA300 may be similar to or included in the memory cell arrays MCA of FIGS. 4 and 5A. The memory cell arrays MCA100, MCA200, and MCA300 may differ in terms of the structure of the transistors in its memory cells, as explained in greater detail below. Hereinafter, as for the detailed description on the constituent element also appearing in FIGS. 4 and 5A, the above-described embodiments of the present disclosure may be referred to.

Referring to FIG. 6, the memory cell array MCA100 may include a plurality of memory cells MC10. The memory cell array MCA100 may include, for example, a three-dimensional array of memory cells MC10. The three-dimensional array of the memory cells MC10 may include a column array of memory cells MC10 and a row array of memory cells MC10. The column array of the memory cells MC10 may include a plurality of memory cells MC10 that are stacked in the first direction D1, and the row array of the memory cells MC10 may include a plurality of memory cells MC10 that are horizontally disposed in the second direction D2 and the third direction D3.

Each memory cell MC10 may include a first conductive line BL, a switching element TR, and a data storage element CAP, for example, as shown in FIGS. 5B to 5D. Hereinafter, as for the detailed description on the first conductive line BL and the data storage element CAP, the above-described embodiments of the present disclosure may be referred to.

The switching element TR may include a nanosheet HL and a second conductive line DWL. The nanosheet HL may extend in the second direction D2. The second conductive line DWL may extend in the third direction D3.

The second conductive line DWL may have a double structure, e.g., a dual-gate structure. For example, the second conductive line DWL may include an upper horizontal (gate) line G1 and a lower horizontal (gate) line G2 that are facing each other, with the horizontal layer HL interposed therebetween. As illustrated in FIG. 5C, a nanosheet dielectric layer GD may be formed on the upper surface and the lower surface of the horizontal layer HL.

Each of the upper horizontal line G1 and the lower horizontal line G2 may include a pair of flat sidewalls FSW extending in the third direction D3. The flat sidewalls FSW may be vertical sidewalls. The flat sidewalls FSW may have a linear shape extending in the third direction D3.

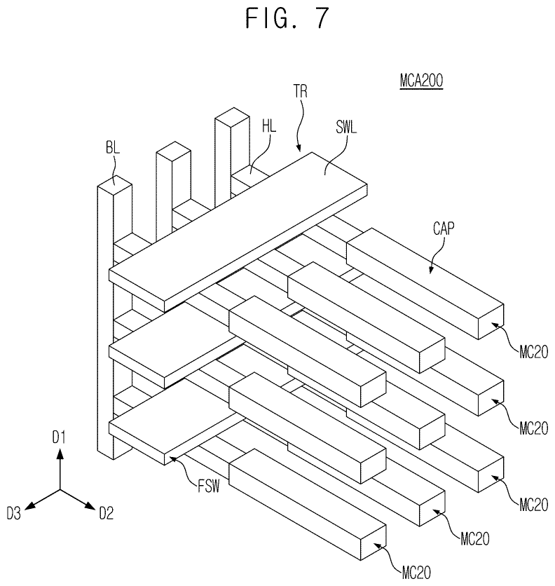

Referring to FIG. 7, the memory cell array MCA200 may include a plurality of memory cells MC20. The memory cell array MCA200 may include a three-dimensional array of memory cells MC20. The three-dimensional array of the memory cells MC20 may include a column array of memory cells MC20 and a row array of memory cells MC20. The column array of the memory cells MC20 may include a plurality of memory cells MC20 that are stacked in the first direction D1, and the row array of the memory cells MC20 may include a plurality of memory cells MC20 that are horizontally disposed in the second direction D2 and the third direction D3.

Each of the memory cells MC20 may include a first conductive (bit) line BL, a switching element TR, and a data storage element (e.g., capacitor) CAP. The first conductive line BL and the data storage element CAP may be similar to the ones previously described, for example, with reference to FIGS. 5A to 5D.

The switching element TR may include a nanosheet HL and a second conductive line SWL. The nanosheet HL may extend in the second direction D2. The second conductive line SWL may extend in the third direction D3.

The second conductive line SWL may be a gate line which has a single structure, as opposed to the double structure of the second conductive line DWL shown in FIG. 6. For example, the second conductive line SWL may be disposed in the upper portion of the nanosheet HL. As illustrated in FIG. 5C, a nanosheet dielectric layer GD may be formed between the upper surface of the nanosheet HL and the second conductive line SWL. According to another embodiment of the present disclosure, the second conductive line SWL may be disposed in the lower portion of the nanosheet HL.

The second conductive line SWL may include a pair of flat sidewalls FSW extending in the third direction D3. The flat sidewalls FSW may considered to be vertical sidewalls. According to another embodiment of the present disclosure, the second conductive line SWL may include a channel overlapping portion WLP and a channel non-overlapping portion NOL, as illustrated, for example, in FIG. 5D.

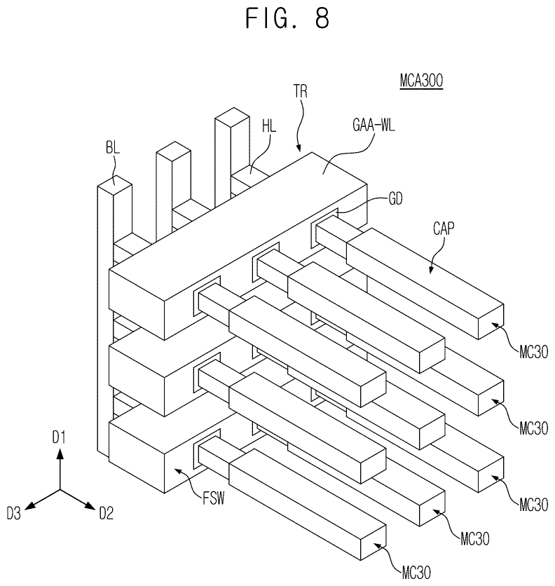

Referring to FIG. 8, the memory cell array MCA300 may include a plurality of memory cells MC30. The memory cell array MCA300 may include a three-dimensional array of memory cells MC30. The three-dimensional array of the memory cells MC30 may include a column array of memory cells MC30 and a row array of memory cells MC30. The column array of the memory cells MC30 may include a plurality of memory cells MC30 that are stacked in the first direction D1, and the row array of the memory cells MC30 may include a plurality of memory cells MC30 that are horizontally disposed in the second direction D2 and the third direction D3.

Each memory cell MC30 may include a first conductive (bit) line BL, a switching element TR, and a data storage element CAP. Hereinafter, as for the detailed description on the first conductive line BL and the data storage element CAP, the above-described embodiments of the present disclosure may be referred to.

The switching element TR may include a nanosheet HL and a second conductive (gate or word) line GAA-WL. The nanosheet HL may extend in the second direction D2. The second conductive line GAA-WL may extend in the third direction D3.

The second conductive line GAA-WL may be a Gate-All-Around Structure GAA. For example, the second conductive line GAA-WL may extend in the third direction D3 while surrounding the nanosheets HL of the same horizontal level. A nanosheet dielectric layer GD may be formed between the nanosheet HL and the second conductive line GAA-WL. The nanosheet dielectric layer GD may surround each nanosheet HL. The second conductive line GAA-WL may include a pair of flat sidewalls FSW extending in the third direction D3. The flat sidewalls FSW may be vertical sidewalls.

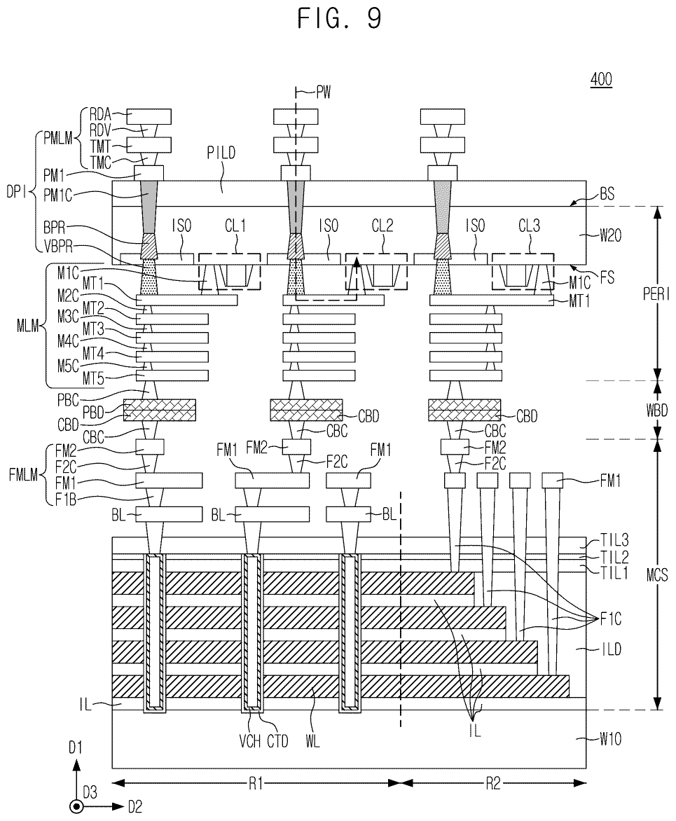

FIG. 9 illustrates another semiconductor device 400 in accordance with another embodiment of the present disclosure.

Referring to FIG. 9, the semiconductor device 400 may include a memory cell string MCS, a peripheral circuit PERI, a bonding structure WBD between the memory cell string MCS and the peripheral circuit PERI, and a Direct Power Interconnection DPI coupled to the peripheral circuit PERI. The Direct Power Interconnection DPI may be any of the same structures shown in FIG. 1 or 2.

The memory cell string MCS may form a three-dimensional vertical NAND memory. The memory cell string MCS may be disposed over the first substrate W10, and the memory cell string MCS may include a front multi-level metal line FMLM. A first bonding contact plug CBC and a first bonding pad CBD may be formed over the front multi-level metal line FMLM. The memory cell string MCS may include a first region R1 and a second region R2. The first region R1 may be a region where memory cells are formed, and the second region R2 may be a region where cell contact plugs coupled to the memory cells are formed. The second region R2 may have a stepped structure.

The memory cell string MCS may include an alternating stack in which word lines WL and inter-word line dielectric layers IL are alternately stacked. The memory cell string MCS may further include vertical channels VCH penetrating the alternating stack, memory layers CTD surrounding the vertical channels VCH, and a plurality of bit lines BL coupled to upper end portions of respective ones of the vertical channels VCH. The memory layer CTD may include a stack of a tunnel dielectric layer, a charge storage layer, and a gate dielectric layer.

The memory cell string MCS and the peripheral circuit PERI may be interconnected to each other by the bonding structure WBD. The memory cell string MCS and the peripheral circuit PERI may be bonded with each other by a wafer bonding process. In other words, the memory cell string MCS and the peripheral circuit PERI may be bonded with each other by a wafer bonding structure WBD.

The peripheral circuit PERI may include at least one control circuit CL for driving the memory cell array MCA. The peripheral circuit PERI may be formed in the second substrate W20 and may further include multi-level metal lines MLM that are coupled to a plurality of control circuits CL1, CL2, and CL3, respectively. Each of the multi-level metal lines MLM may include a plurality of metal lines MT1 to MT5 and a plurality of metal contact plugs M1C to M5C. For example, each of the multi-level metal lines MLM may include at least one first level metal line MT1 and at least one first level metal contact plug M1C. The first level metal line MT1 and the first level metal contact plug M1C may be coupled to corresponding ones of the control circuits CL1, CL2, and CL3. A plurality of isolation layers ISO may be formed in the second substrate W20. Each isolation layer ISO may be disposed between an adjacent pair of the control circuits CL1, CL2, and CL3. The isolation layers ISO may have a Shallow Trench Isolation (STI) structure. The second substrate W20 may include a front side FS and a back side BS, and the back side BS of the second substrate W20 may be disposed at a higher level than the front side FS. The second substrate W20 may be flipped over by wafer flipping such that the back side BS is disposed at a higher level than the front side FS. The first level metal line MT1 and the first level metal contact plug M1C of the multi-level metal line MLM may be included in a power transmission path PW.

The direct power interconnection DPI may include a buried power rail BPR buried in the second substrate W20, a buried power rail via VBPR coupled to a first surface of the buried power rail BPR, a post power via PM1C coupled to a second surface of the buried power rail BPR, a post power metal line PM1 coupled to the post power via PM1C, and a post-multi-level metal line PMLM coupled to the post power metal line PM1. The first surface of the buried power rail BPR may be electrically connected to the first level metal contact plug MIC and the first level metal line MT1 of the multi-level metal line through the buried power rail via VBPR, and the second surface of the buried power rail BPR may be electrically connected to the post power via PM1C and the power metal line PM1. The post-multi-level metal line PMLM may include a plurality of post metal lines TMT and RDA and a plurality of post vias TMC and RDV interleaved between the plurality of post metal lines TMT and RDA. The post power via PM1C and the post power metal line PM1 may be part of the post-multi-level metal line PMLM.

Each buried power rail via VBPR may extend from the inside of a corresponding one of the isolation layers ISO and may extend from the front side FS of the second substrate W20. The buried power rail BPR may extend inside the second substrate W20 at a location adjacent to the front side FS of the second substrate W20. The buried power rail BPR may at least partially extend into a corresponding one of the isolation layers ISO. The vertical structure of the post power via PM1C, the buried power rail BPR, and the buried power rail via VBPR may be a structure that penetrates the post inter-layer dielectric layer PILD, the second substrate W20, and the isolation layers ISO.

The direct power interconnection DPI may function to directly transmit power from the back side BS of the second substrate W20. In other words, the direct power interconnection DPI may be a Back-Side Power Distribution Network (BSPDN) for transmitting power to the control circuits CL1, CL2, and CL3.

As described above, the semiconductor device 400 may be a POC (PERI-over-Cell array) structure in which the memory cell string MCS, the bonding structure WBD, and the peripheral circuit PERI are sequentially stacked in this order. The control circuits CL1, CL2, and CL3 of the peripheral circuit PERI may be electrically connected to the memory cell array MCA through the bonding structure WBD.

The semiconductor device 400 may directly supply power to the control circuits CL, CL1, and CL2 of the peripheral circuit PERI through the direct power interconnection DPI, the first level metal line MT1, and the first level metal contact plug M1C. Accordingly, the path (see reference symbol ‘PW’) for transmitting power to the control circuits CL1, CL2, and CL3 may be shortened, thereby reducing power consumption. The power transmission path PW may include a post-multi-level metal line PMLM, a power metal line PM1, a post power via PM1C, a buried power rail BPR, a buried power rail via VBPR, a first level metal line MT1, and a first level metal contact plug M1C.

As described above, a method of supplying power to the control circuits CL1, CL2, and CL3 in the semiconductor device 400 may be a top-down power supply from the post-multi-level metal line PMLM to the control circuits CL1, CL2, and CL3.

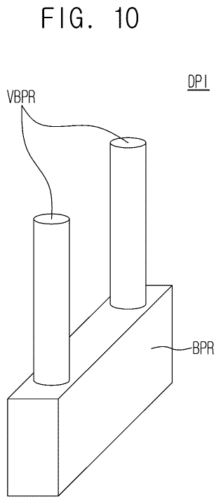

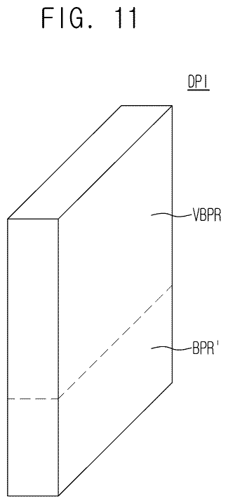

FIGS. 10 and 11 illustrate an example of the direct power interconnection in accordance with another embodiment of the present disclosure.

Referring to FIG. 10, the buried power rail BPR′ and the buried power rail via VBPR of the direct power interconnection DPI may be formed individually. In other words, the buried power rail via VBPR may be a structure where the buried power rail via VBPR is a separate structure coupled to the buried power rail BPR′.

Referring to FIG. 11, the buried power rail BPR′ and the buried power rail via VBPR of the direct power interconnection DPI may have an integrated structure, and the buried power rail BPR′ may also serve as the buried power rail via VBPR. For example, a portion where the buried power rail via VBPR is to be formed may be formed simultaneously while the buried power rail BPR′ is formed.

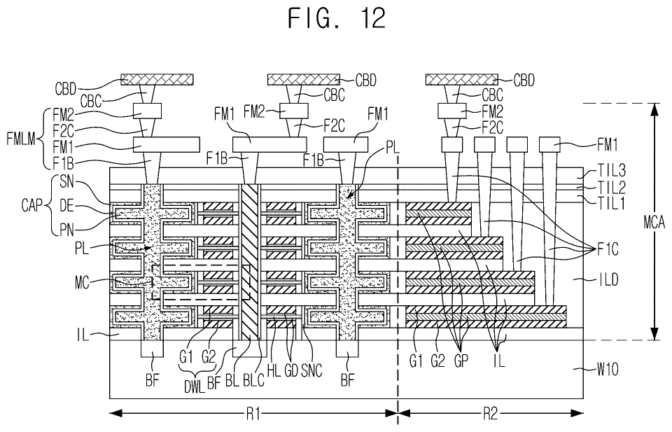

FIGS. 12 to 23 illustrate an example of a method for fabricating the semiconductor device shown in FIG. 4.

Referring to FIG. 12, the memory cell array MCA may be formed over the first substrate W10. The first substrate W10 may be a material appropriate for semiconductor processing. For example, the first substrate W10 may include at least one of a conductive material, a dielectric material, or a semiconductive material. The first substrate W10 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The first substrate W10 may further include another semiconductor material such as germanium. The first substrate W10 may further include a semiconductor substrate formed from a Group III/V material, for example, a compound semiconductor substrate, such as gallium arsenide (GaAs). The first substrate W10 may include an SOI (Silicon-On-Insulator) substrate.

The memory cell array MCA may include a three-dimensional array of memory cells MC, as shown, for example, in FIGS. 6 to 8. Each memory cell MC may include a first conductive line BL, a switching element TR, and a data storage element CAP. The switching element TR may include a nanosheet HL, a nanosheet dielectric layer GD, and a second conductive line DWL. Hereinafter, as for the detailed description on the memory cell array MCA, having memory cells MC as shown, for example, in FIGS. 5A to 5D.

The memory cell array MCA may include a first region R1 and a second region R2. The first region R1 may be a region where memory cells MC are formed, and the second region R2 may be a region where cell contact plugs coupled to the memory cells MC are formed. The second conductive lines DWL of the first region R1 may extend horizontally to the second region R2, and the second conductive lines DWL of the second region R2 may have a stepped structure. In the second region R2 of the memory cell array MCA, each step of the stepped structure may include an upper horizontal line G1, a lower horizontal line G2, and a pad GP between the upper horizontal line G1 and the lower horizontal line G2.

A front multi-level metal line FMLM may be formed over the memory cell array MCA. The front multi-level metal line FMLM may be an array-side interconnection structure. The front multi-level metal line FMLM may include first front vias F1B, first front contact plugs F1C, first front metal lines FM1, second front vias F2C, and second front metal lines FM2. The first front vias F1B may penetrate a third hard mask layer TIL3 to be coupled to a first conductive line BL and a common plate PL, respectively. The upper and lower horizontal lines G1 and G2 of the second conductive lines DWL in the second region R2 of the memory cell array MCA may be coupled to the first front contact plugs F1C and the first front metal lines FM1.

First bonding contact plugs CBC and first bonding pads CBD may be formed over the second front metal lines FM2 of the front multi-level metal line FMLM.

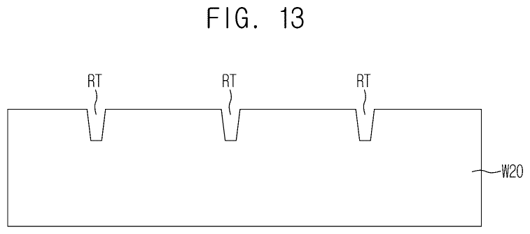

Referring to FIG. 13, rail-shaped trenches RT may be formed in the second substrate W20. Portions of the second substrate W20 may be etched to form the rail-shaped trenches RT. The second substrate W20 may be a material appropriate for semiconductor processing. The second substrate W20 may include at least one among a conductive material, a dielectric material, and a semiconductive material. The second substrate W20 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The second substrate W20 may further include another semiconductor material, such as germanium. The second substrate W20 may further include a III/V-group semiconductor substrate, for example, a compound semiconductor substrate, such as gallium arsenide (GaAs). The second substrate W20 may include an SOI (Silicon-On-Insulator) substrate.

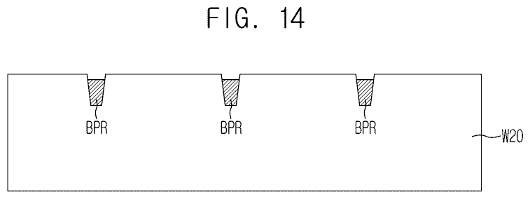

Referring to FIG. 14, buried power rails BPR may be formed to at least partially fill the rail-shaped trenches RT. Forming the buried power rails BPR may include processes of depositing and etching a conductive material. The buried power rails BPR may include polysilicon, a metal, or a combination thereof.

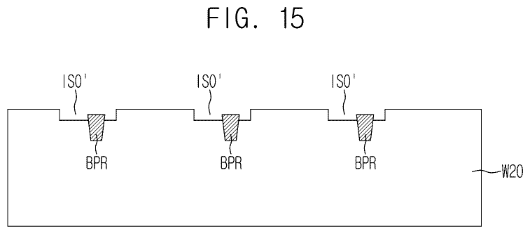

Referring to FIG. 15, portions of the second substrate W20 may be etched to form isolation trenches ISO′ that expose the upper end portions of the buried power rails BPR.

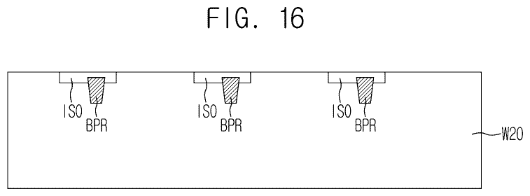

Referring to FIG. 16, isolation layers ISO may be formed to fill the isolation trenches ISO′. The isolation layers ISO may include silicon oxide, silicon nitride, or a combination thereof. According to another embodiment of the present disclosure, the buried power rails BPR may be formed after the isolation layers ISO are formed.

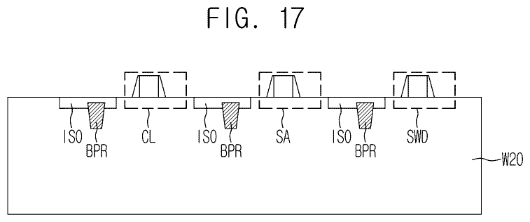

Referring to FIG. 17, a plurality of transistors for control circuits CL, SA and SWD (arranged adjacent to the isolation layers ISO) may be formed over the second substrate W20. The transistors may include a gate, a gate spacer, and a source/drain. The control circuits CL, SA and SWD may include a common plate control circuit CL, sub-word line drivers SWD, and a sense amplifier SA.

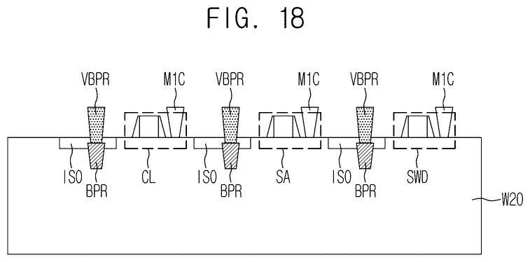

Referring to FIG. 18, first level metal contact plugs M1C may be formed to be coupled to the control circuits CL, SA and SWD, respectively, at locations adjacent to the transistors. While the first level metal contact plug M1C is formed, buried power rail vias VBPR coupled to the buried power rails BPR may be formed, e.g., may simultaneously be formed with the first level metal contact plugs M1C. The first level metal contact plug M1C and the buried power rail vias VBPR may include a metal-based material.

Forming the first level metal contact plug M1C and the buried power rail vias VBPR may include forming an inter-layer dielectric layer, forming contact holes and via holes in the inter-layer dielectric layer, forming the first level metal contact plug M1C in the contact holes, and forming the buried power rail vias VBPR in the via holes. Forming the first level metal contact plug M1C and forming the buried power rail vias VBPR may be performed simultaneously.

Referring to FIGS. 13 to 18, a plurality of control circuits CL, SA and SWD may be formed in (e.g., embedded in) the front side FS of the substrate W20 including the back side and the front side. A buried power interconnection may be formed to be partially buried in the second substrate W20 from the front side FS and may be coupled to respective ones of the control circuits CL, SA and SWD. Here, the buried power interconnection may include a combination of the buried power rail BPR and the buried power rail via VBPR.

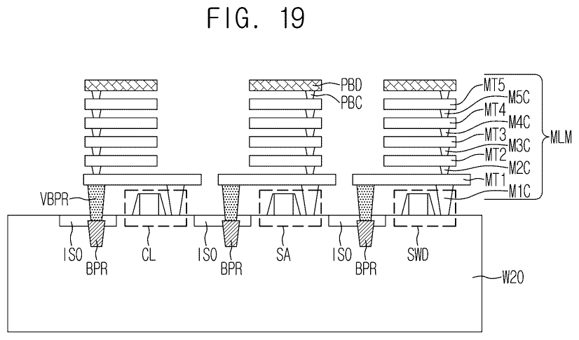

Referring to FIG. 19, multi-level metal lines MLM may be formed. Each multi-level metal line MLM may have a structure of at least five layers. For example, each multi-level metal line MLM may include a plurality of metal lines MT1 to MT5 and a plurality of metal contact plugs M2C to M5C. Each multi-level metal line MLM may have a front-side interconnection structure that is coupled to the buried power interconnection of the buried power rail BPR and the buried power rail via VBPR. The multi-level metal lines MLM may include a first-level metal contact plug M1C of FIG. 18. The buried power rail BPR may be electrically connected to the first level metal contact plug M1C and the first level metal line MT1 of the multi-level metal lines MLM through the buried power rail via VBPR. A second bonding contact plug PBC and a second bonding pad PBD may be formed over each of the multi-level metal lines MLM.

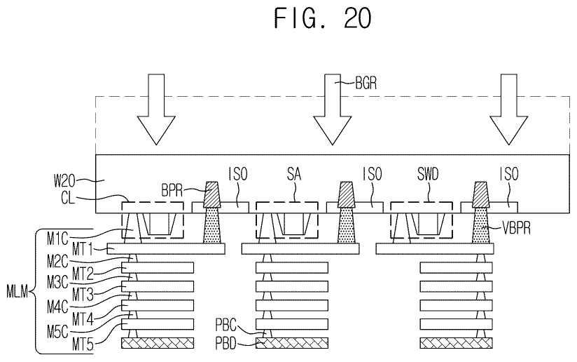

Referring to FIG. 20, after the multi-level metal lines MLM are formed, the second substrate W20 may be flipped over. For example, the second substrate W20 may be flipped over by wafer flipping such that the back side of the second substrate W20 may be disposed at a higher level than the front side. The second bonding pad PBD may be disposed at the lowermost level by the wafer flipping. Subsequently, back grinding BGR (e.g., Chemical Mechanical Polishing (CMP)) may be performed to decrease the thickness of the back side of the second substrate W20.

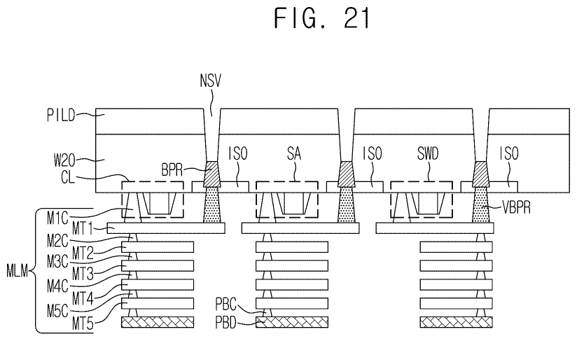

Referring to FIG. 21, a post inter-layer dielectric layer PILD may be formed on the back side of the second substrate W20. After the post inter-layer dielectric layer PILD is etched, the back side of the second substrate W20 may be etched to have a predetermined thickness. Accordingly, nano-through silicon vias NSVs exposing the buried power rails BPR may be formed.

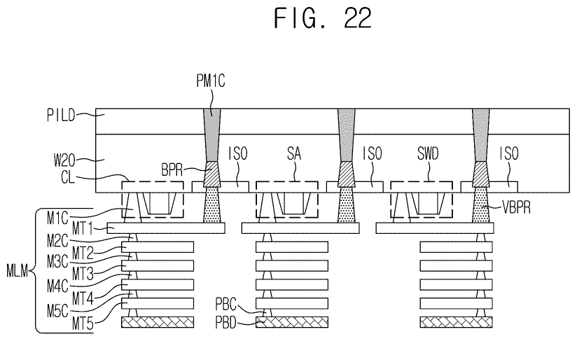

Referring to FIG. 22, post power vias PM1C may be formed to fill the nano-through silicon vias NSV. The post power vias PM1C may include a metal-based material. The post power vias PM1C may be referred to as nano-through silicon vias NTSV.

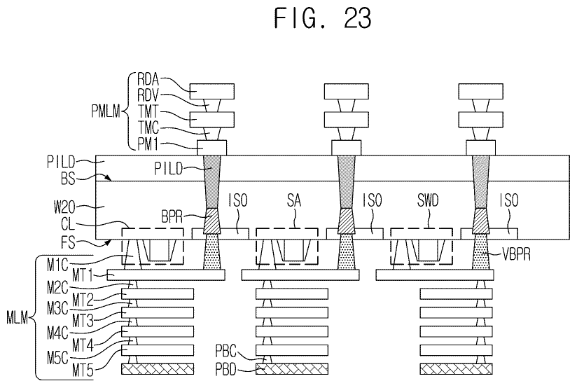

Referring to FIG. 23, a post power metal line PM1 may be formed over the post power via PM1C, and a post-multi-level metal line PMLM may be formed over the post power metal line PM1. The post-multi-level metal line PMLM may include post metal lines TMT and RDA and post vias TMC and RDV. The post power metal line PM1 may be a portion of the post-multi-level metal line PMLM. The post power via PM1C, the post power metal line PM1 and the post-multi-level metal line PMLM may have a back side interconnection structure.

Referring to FIGS. 21 to 23, the back side interconnection structure may be formed to extend downward from the back side BS of the second substrate W20 that is flipped and back-grounded and is coupled to the buried power rail BPR and the buried power rail via VBPR of the buried power interconnection.

Subsequently, referring to FIG. 4, a bonding process for electrical connection between the memory cell array MCA and the control circuits CL, SA and SWD may be performed. The bonding may be performed using the bonding structure WBD. For example, a wafer bonding process of the first substrate W10 and the second substrate W20 may be performed to bond the first bonding pad CBD and the second bonding pad PBD of the bonding structure WBD.

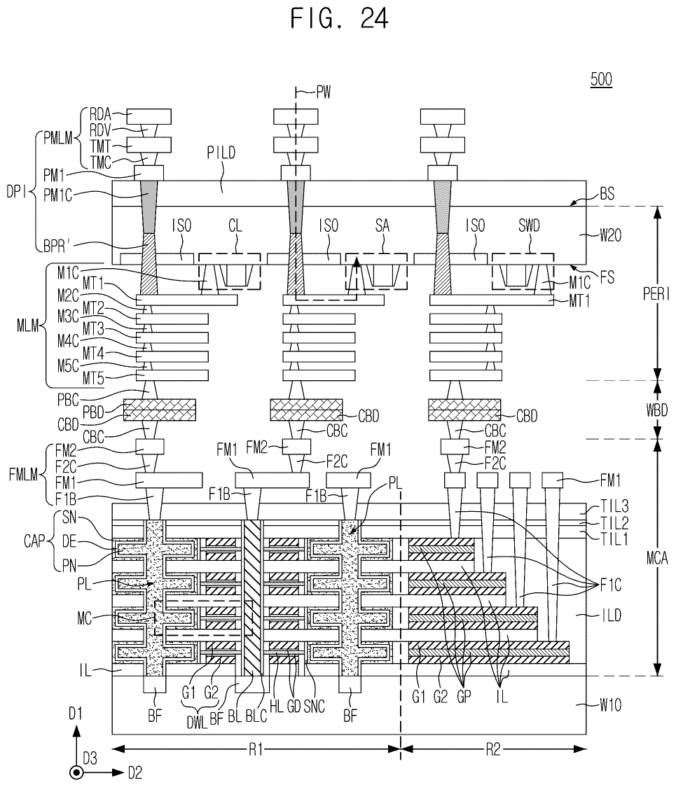

FIG. 24 is a schematic cross-sectional view illustrating a semiconductor device 500 in accordance with another embodiment of the present disclosure. FIG. 24 illustrates a stacked semiconductor device including the buried power rails BPR′ of FIG. 11, which, for example, replace the configuration of the buried power rail BPR and buried power rail via VBPR of FIG. 4. In other respects, the semiconductor device 500 of FIG. 24 may be similar to the semiconductor device 200 of FIG. 4. Hereinafter, as for the detailed description on the constituent element also appearing in FIG. 4, FIG. 4 may be referred to.

Referring to FIG. 24, the semiconductor device 500 may include a memory cell array MCA, a peripheral circuit PERI, a bonding structure WBD between the memory cell array MCA and the peripheral circuit PERI, and a direct power interconnection DPI coupled to the peripheral circuit PERI. See FIGS. 1 and 4 for examples of a description on the direct power interconnection DPI.

The direct power interconnection DPI may include a buried power rail BPR′ (that also serves as the buried power rail via), a post power via PM1C coupled to the buried power rail BPR, a post power metal line PM1 coupled to the post power via PM1C, and a post-multi-level metal line PMLM coupled to the post power metal line PM1. A first surface of the buried power rail BPR′ may be electrically connected to the first level metal contact plug M1C and the first level metal line MT1 of the multi-level metal line. A second surface of the buried power rail BPR′ may be electrically connected to the post power via PM1C and the post power metal line PM1. The post-multi-level metal line PMLM may include a plurality of post metal lines TMT and RDA and a plurality of post vias TMC and RDV interleaved between the plurality of post metal lines TMT and RDA. The post power via PM1C and the post power metal line PM1 may be part of the post-multi-level metal line PMLM.

Referring to FIG. 24, the buried power rails BPR′ may thus have an integrated structure including the buried power vias.

The above-described embodiments of the present disclosure may directly supply power to the transistors of the peripheral circuit unit in the stacked semiconductor device. This is a technology for supplying optimal power when the stacked semiconductor device including the memory cell array and the peripheral circuit is formed by wafer bonding. The buried power rail for supplying power may be buried in the substrate during the process of forming an isolation layer. The buried power rail may be directly coupled to a transistor through a metal line and a metal contact plug.

According to the embodiment of the present disclosure, because a direct power interconnection is formed to penetrate the substrate where the control circuits of the peripheral circuit are formed, the process of etching a high aspect ratio contact may be omitted, thereby reducing the cost for fabricating a semiconductor device.

According to the embodiment of the present disclosure, the path for supplying power to the control circuits of the peripheral circuit may be reduced by wafer-bonding the memory cell array and the peripheral circuit in such a manner that the peripheral circuit is disposed at a higher level than the memory cell array, and forming a direct power interconnection for directly supplying power to the control circuits of the peripheral circuit. Therefore, the power consumption and resistance of the semiconductor device may be reduced.

While the present disclosure has been described with respect to the specific embodiments, it will be apparent to those skilled in the art that various changes and modifications may be made without departing from the spirit and scope of the invention as defined in the following claims. The embodiments may be combined to form additional embodiments.

What is claimed is:

1. A semiconductor device, comprising:
a first substrate;
a memory cell array including memory cells that are vertically stacked over the first substrate;
a second substrate including a front side facing the memory cell array and a back side at a higher level than the front side, and including a plurality of control circuits;
a back-side power distribution network including a power interconnection that penetrates the second substrate and supplies power to the control circuits from the back side of the second substrate.

2. The semiconductor device of claim 1, further comprising:
a metal contact plug and a metal line suitable for interconnecting the power interconnection and the plurality of control circuits to each other.

3. The semiconductor device of claim 1, wherein the back-side power distribution network includes:
a post multi-level metal line to which power is supplied;
a buried power rail via electrically connected to the control circuits; and
a buried power rail disposed between the buried power rail via and the post multi-level metal line, wherein the buried power rail is buried in the second substrate and the buried power rail via is partially buried in the second substrate.

4. The semiconductor device of claim 3, wherein the buried power rail via is coupled to the buried power rail.

5. The semiconductor device of claim 3, wherein the buried power rail and the buried power rail via have an integrated structure.

6. The semiconductor device of claim 1, further comprising:
isolation layers between the plurality of control circuits,
wherein the power interconnection penetrates the second substrate and the isolation layers.

7. The semiconductor device of claim 1, further comprising:
a front multi-level metal line coupled to the memory cell array at a higher level than the memory cell array;
a first bonding pad coupled to an upper end portion of the front multi-level metal line;
a multi-level metal line coupled to the plurality of control circuits at a lower level than the plurality of control circuits; and
a second bonding pad coupled to a lower end portion of the multi-level metal line, wherein the first bonding pad and the second bonding pad have an interconnected structure.

8. The semiconductor device of claim 1, wherein:
the memory cell array includes a three-dimensional array of memory cells that are stacked vertically, and
each of the memory cells includes:
a horizontally oriented nanosheet;
a first conductive line coupled to a first side of the nanosheet and vertically oriented;
a data storage element coupled to a second side of the nanosheet; and
a second conductive line horizontally oriented to cross the nanosheet.

9. The semiconductor device of claim 1, wherein:
the memory cell array includes a three-dimensional array of memory cells that are stacked vertically, and
each of the memory cells includes:
a horizontally oriented nanosheet;
a bit line coupled to a first side of the nanosheet and oriented vertically;
a capacitor coupled to a second side of the nanosheet; and
a word line having a double structure oriented horizontally to cross the nanosheet.

10. The semiconductor device of claim 1, wherein:
the memory cell array includes a three-dimensional array of memory cells that are stacked vertically, and
each of the memory cells includes:
a horizontally oriented nanosheet;
a bit line coupled to a first side of the nanosheet and oriented vertically;
a capacitor coupled to a second side of the nanosheet; and
a word line of a gate all-around structure oriented horizontally while surrounding the nanosheet.

11. A method for fabricating a semiconductor device, comprising:
forming a memory cell array over a first substrate;
forming an array-side interconnection structure that is coupled to the memory cell array;
forming a plurality of control circuits on a front side of a second substrate including a back side and the front side, and a buried power interconnection partially buried in the second substrate from the front side and coupled to the plurality of control circuits;
forming a front-side interconnection structure coupled to the buried power interconnection;
flipping the second substrate after the forming of the front-side interconnection structure;
forming a back-side interconnection structure extending downward from the back side of the flipped second substrate and coupled to the buried power interconnection; and
performing a bonding process for electrically connecting the memory cell array and the plurality of control circuits to each other.

12. The method of claim 11, wherein forming of plurality of control circuits on the front side of the second substrate including the back side and the front side, and the buried power interconnection partially buried in the second substrate from the front side and coupled to the plurality of control circuits, includes:
forming a buried power rail buried in the second substrate from the front side of the second substrate;
forming an isolation layer over the buried power rail;
forming the plurality of control circuits on the front side of the second substrate between the isolation layers; and
forming a buried power rail via coupled to the buried power rail.

13. The method of claim 12, further comprising:
after the forming of the control circuits, forming a metal contact plug coupled to the control circuits, wherein the metal contact plug and the buried power rail via are formed simultaneously.

14. The method of claim 13, further comprising:
after the forming of the metal contact plug, forming a metal line that interconnects the metal contact plug and the buried power rail via.

15. The method of claim 12, wherein:
the buried power rail via is coupled to the buried power rail, or
the buried power rail and the buried power rail via are formed to have an integrated structure.

16. The method of claim 11, wherein forming the front side interconnection structure coupled to the buried power interconnection includes:
forming a nano through-silicon via hole on the back side of the second substrate to expose the buried power interconnection;
forming a nano through-silicon via that fills the nano through-silicon via hole; and
forming a multi-level metal line coupled to the nano through-silicon via.

17. The method of claim 11, further comprising:
after the forming of the array-side interconnection structure that is coupled to the memory cell array, forming a first bonding pad coupled to the array-side interconnection structure.

18. The method of claim 11, further comprising:
after the forming of the front-side interconnection structure coupled to the buried power interconnection, forming a second bonding pad coupled to the front side interconnection structure.

19. The method of claim 11, wherein the bonding process includes direct bonding or hybrid bonding.

20. The method of claim 11, wherein:
forming the memory cell array over the first substrate includes vertically stacking memory cells over the first substrate, and
each of the memory cells includes:
a horizontally oriented nanosheet;
a bit line coupled to a first side of the nanosheet and oriented vertically;
a capacitor coupled to a second side of the nanosheet; and
a word line of a double structure oriented horizontally to cross the nanosheet.
